(19) United States
(12) Patent Application Publication
(10) Pub. No.: US 2007/0155115 A1
(43) Pub. Date: Jul. 5, 2007

(54) Semiconductor device having capacitor large in capacitance and high in reliability and method of manufacturing the same

(75) Inventor: Mitsuhiro Horikawa, Tokyo (JP)

Correspondence Address: YOUNG & THOMPSON, 745 SOUTH 23RD STREET, 2ND FLOOR, ARLINGTON, VA, 22202, US

(73) Assignee: ELPIDA MEMORY INC., TOKYO (JP)

(21) Appl. No.: 11/638,497

(22) Filed: Dec. 14, 2006

(30) Foreign Application Priority Data
Dec. 16, 2005 (JP) 2005-362562

(51) Int. Cl. H01L 21/20; H01L 21/8242

(52) U.S. Cl. 438/396; 438/398; 438/253

(57) ABSTRACT

A method according to the present invention includes forming a silicon nitride film on a lower electrode, oxidizing the silicon nitride film, and forming a dielectric film including aluminum on the oxidized silicon nitride film.

This application claims priority to prior Japanese patent application JP 2005-362562, the disclosure of which is incorporated herein by reference.

### BACKGROUND OF THE INVENTION

The present invention relates to a semiconductor device and a method of manufacturing a semiconductor device, and more particularly to a semiconductor device having a capacitor and a method of manufacturing a capacitor in a semiconductor device.

Semiconductor devices have increasingly been scaled up and highly integrated. For example, a dynamic random access memory (DRAM) having a memory capacity of 1 GB has been developed as a large-scale device. On the other hand, an area of memory cells in a DRAM is reduced for the purpose of integration, and thus an effective area of cell capacitors is also reduced.

In order to stably operate a DRAM, it is necessary to maintain at least a certain cell capacitance. A variety of ideas and devices have been produced to maintain at least a certain cell capacitance. For example, there have been proposed and developed use of a capacitor over bit-line structure (COB), in which cell capacitors are disposed on a bit line, and a hemispherical silicon grain structure (HSG) for increasing an electrode area of capacitors. There have been further proposed and developed use of a high-dielectric film.

There has been known a semiconductor device having metal insulator semiconductor (MIS) capacitors using a high-dielectric film.

An MIS capacitor has an electrode made of metal, an electrode made of semiconductor, and a dielectric (insulator) interposed between the electrodes. More specifically, an MIS capacitor is formed by an electrode of polycrystalline silicon to which an impurity (dopant) is added, a high-dielectric film, and an electrode of a metal thin film.

Materials having a permittivity several times higher than a conventional silicon oxide film are used for a high-dielectric film. Examples of the high-dielectric film include a silicon nitride film, an alumina (Al₂O₃) film, and an aluminate film containing aluminum, such as HfAlO, TaAlO, and ZrAlO.

However, an MIS capacitor with a high-dielectric film has the following problems.

A first problem is that a dopant contained in a lower electrode of polycrystalline silicon gets out of the lower electrode so as to increase depletion.

A second problem is that characteristics are degraded at an interface between the lower electrode of polycrystalline silicon and the high-dielectric film of an Al₂O₃ film having a low oxygen diffusibility or an aluminate film containing Al.

The capacitance C of an MIS capacitor is represented by C=∈S/t where S is an area of the electrode, ∈ is a permittivity of the dielectric, and t is a thickness of the dielectric. Thus, the capacitance C is increased with a high permittivity ∈ and a small film thickness t of the dielectric. A dopant is added to a semiconductor of a lower electrode in an MIS capacitor in order to bring the semiconductor into a conductor. N-type polycrystalline silicon to which a dopant of phosphorus is added is used for lower electrodes of MIS capacitors in currently produced DRAMs.

In an MIS capacitor thus constructed, when an upper electrode made of metal has a negative potential, charge depletion, in which most of electrons serving as carriers are eliminated from an n-type silicon, occurs near a dielectric of a lower electrode made of a semiconductor. In such a region, the charge Q stored in a depletion layer can be represented by qN_{D}d where d is a width (thickness or depth) of the depletion layer, q is an elementary charge, and N_{D} is a concentration of activated phosphorus. Accordingly, an application of a voltage to such an MIS capacitor is equivalent to an increase of the thickness of the dielectric by the width of the depletion layer in the n-type polycrystalline silicon. Specifically, the capacitance is reduced by the width of the depletion layer. The width d of the depletion layer is inversely proportional to a square root of the phosphorus concentration N_{D}. Accordingly, the width d of the depletion layer can be reduced by increasing the phosphorus concentration N_{D}.

For example, a first reference (Japanese laid-open patent publication No. 2001-24165) discloses an invention for solving the above problems. Specifically, after formation of a silicon electrode, a heat treatment is performed under an atmosphere including phosphine (PH₃) in order to increase the phosphorus concentration. Then, a dielectric of tantalum pentoxide (Ta₂O₅) or the like is formed, and a metal electrode of titanium nitride (TiN) or the like is subsequently formed.

However, the silicon electrode is oxidized at the time of the formation of Ta₂O₅ or the like, so that a silicon oxide film is formed between the silicon electrode and Ta₂O₅. In this case, the silicon oxide film has a permittivity lower than Ta₂O₅. Accordingly, the capacitance becomes small. Particularly, silicon having a high phosphorus concentration is likely to be oxidized. In the first reference, a silicon nitride film is formed to prevent oxidation of the silicon electrode after the heat treatment under PH₃. If a wafer subjected to the heat treatment under PH₃ is returned to an atmosphere, then a surface of silicon containing a large amount of phosphorus is oxidized. Accordingly, in the first reference, the silicon nitride film is formed in a state such that a wafer subjected to the heat treatment under PH₃ is not exposed to an atmosphere.

If a silicon oxide film is formed on the surface of the silicon electrode by exposure of the PH₃ annealed wafer to an atmosphere, it is necessary to remove the silicon oxide film by etching. In this case, the phosphorus concentration is lowered at the interface. Accordingly, it is necessary to dope an impurity by PH₃ annealing and also to form a silicon nitride film for oxidation prevention in a state such that the wafer is not exposed to an atmosphere. Formation of the silicon nitride film on the silicon electrode is advantageous in that oxidation can be prevented at the interface between Ta₂O₅ and the silicon electrode during a subsequent heat treatment. The foregoing description is a summary of the first reference.

The heat treatment after deposition of Ta₂O₅ has purposes of crystallizing Ta₂O₅ and of eliminating impurities contained in a material when Ta₂O₅ was deposited by chemical vapor deposition (CVD). The heat treatment is performed mostly under an oxidizing atmosphere in order to prevent oxygen deficiency in the Ta₂O₅ film. With the heat treatment under an oxidizing atmosphere, an interface between the silicon electrode and the Ta₂O₅ film is oxidized to some extent. The aforementioned silicon nitride film inhibits the oxidation at the interface, Since the silicon oxide film has a band gap larger than Ta₂O₅ and is amorphous, a certain amount of oxidation is required to reduce a leakage current. However, if the silicon oxide film is present at the interface between the silicon electrode and the Ta₂O₅ film, then the capacitance is problematically reduced as described above.

Specifically, it is necessary to adjust the thickness of the silicon oxide film at the interface between the Ta₂O₅ and the silicon electrode so that the capacitance is not less than a desired value while a leakage current is reduced to a desired level. The thickness and quality of the silicon nitride film and the heat treatment temperature after the deposition of the Ta₂O₅ film are important to the adjustment of the thickness of the silicon oxide film at the interface. When a heat treatment is performed on the silicon nitride film for oxidation protection, the silicon nitride film is not converted into a silicon oxide film but a silicon oxynitride film. Specifically, the silicon nitride film is not converted into a complete silicon oxide film. However, even if there is no clear difference in the thickness of the silicon oxide film at the interface, the reliability (time to breakdown tBD) of the capacitor is improved by the heat treatment under an oxidizing atmosphere. The first reference describes that this effect can be obtained not only in a case of Ta₂O₅ but also in other cases of perovskite dielectric materials such as SrTiO₃ and BaSrTiO₃.

A second reference (Japanese laid-open patent publication No. 2005-11904) discloses a deposition method in a case where an Al₂O₃film or HfO₂ is used as a dielectric film of a DRAM capacitor. A dielectric film on a lower electrode includes an Al₂O₃ film formed by an atomic layer deposition (ALD) and HfO₂ formed by an MOCVD method. The Al₂O₃ dielectric film formed by an ALD method has an excellent step coverage and fewer impurities contained therein.

Further, a third reference (Japanese laid-open patent publication No. 2004-320022) discloses forming a metal film and doped polysilicon as an upper electrode of a capacitor and performing a low-temperature treatment to improve a leakage current.

A fourth reference (Japanese laid-open patent publication No. 10-303368) discloses a capacitor having a diffusion barrier layer and a dielectric layer in which an impurity is doped into an HSG structure of a lower electrode.

As described above, various improvements have been made for capacitors used in semiconductor devices. However, when a high-dielectric film of Ta₂O₅ is used, an oxygen treatment is required to crystallize the Ta₂O₅ film. The oxygen treatment converts a surface of a silicon nitride film as an antioxidant film into a silicon oxynitride film. The oxynitride film is necessary to prevent a leakage current. If a leakage current can actually be prevented, then the surface of the silicon nitride film at an interface is converted into a silicon oxide film rather than a silicon oxynitride film. In such a case, the actual permittivity is lowered by an increase of the film thickness of the dielectric film. Accordingly, the capacitance is problematically reduced.

### SUMMARY OF THE INVENTION

In view of the aforementioned problems, an object of the present invention is to provide a semiconductor device having a capacitor which has a large capacitance, can prevent a leakage current, and has a high reliability, and a method of manufacturing such a semiconductor.

According to an aspect of this invention, there is provided a method of manufacturing a semiconductor device in which a capacitor is formed, the capacitor having a lower electrode made of polycrystalline silicon and a dielectric film including aluminum. The method comprises the steps of doping an impurity into the lower electrode, of forming a silicon nitride film on the lower electrode without exposure to an atmosphere subsequently to the doping step of the impurity, of oxidizing the silicon nitride film, and of forming the dielectric film on the oxidized silicon nitride film.

According to another aspect of this invention, there is provided a semiconductor device comprising the capacitor manufactured by the semiconductor device manufacturing method.

### BRIEF DESCRIPTION OF THE DRAWINGS

FIG. 1 is a schematic view showing a single-wafer processing apparatus used for a method of manufacturing a capacitor according to the present invention;

FIG. 2 is a schematic view showing a batch type wafer processing apparatus used for a method of manufacturing a capacitor according to the present invention;

FIG. 3A is a cross-sectional view showing a semiconductor device after formation of a lower electrode of polycrystalline silicon for the purpose of explaining a method of manufacturing a capacitor according to the present invention;

FIG. 3B is a cross-sectional view showing the semiconductor device after formation of an HSG on a surface of the polycrystalline silicon for the purpose of explaining a method of manufacturing a capacitor according to the present invention; and

FIG. 4 is a graph showing evaluative effects of a method of manufacturing a capacitor according to the present invention.

### DESCRIPTION OF THE PREFERRED EMBODIMENTS

In a method of manufacturing a capacitor according to the present invention, a silicon nitride film is directly oxidized to thereby limit reformation of the silicon nitride film to a minimum range. With this method, it is possible to prevent a leakage current and reduction of a capacitance. Further, the method of manufacturing a capacitor according to the present invention can reform the silicon nitride film so as to improve the quality of a dielectric film.

A semiconductor device and a method of manufacturing a semiconductor device according to embodiments of the present invention will be described below with reference to FIGS. 1 to 4.

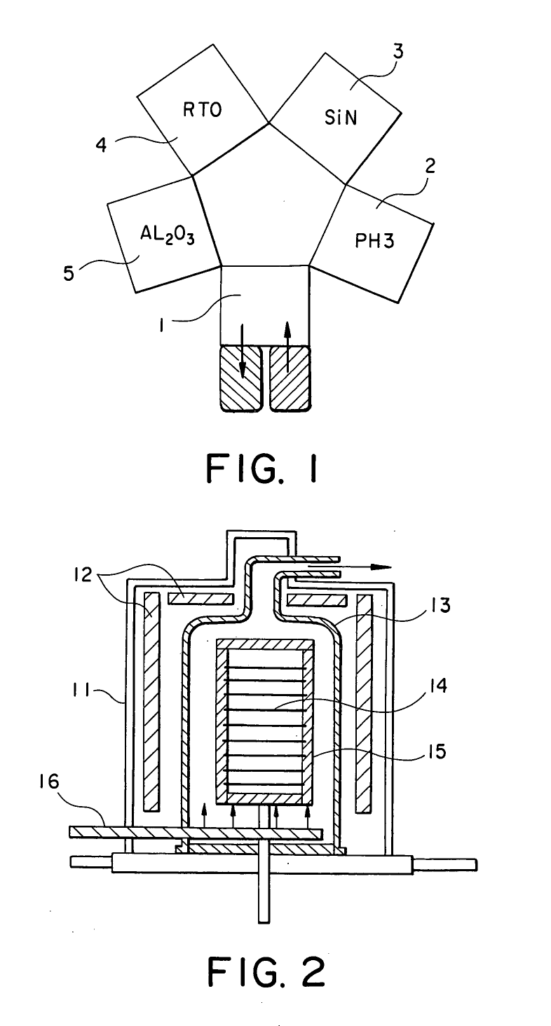

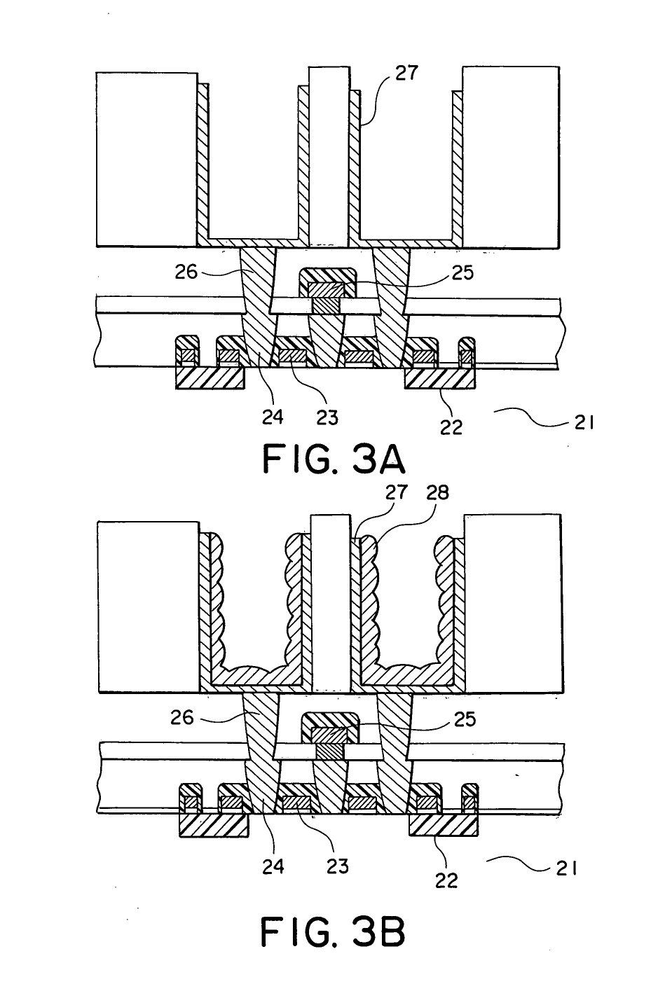

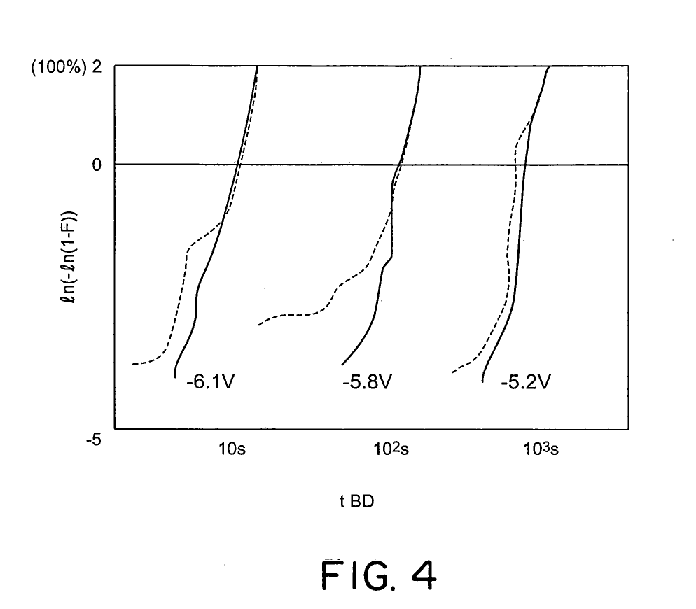

FIGS. 1 and 2 are schematic views showing wafer processing apparatuses for implementing the present invention. FIG. 1 shows a single-wafer processing apparatus, and FIG. 2 shows a batch type wafer processing apparatus. FIGS. 3A and 3B are cross-sectional views showing a semiconductor device during a manufacturing process. FIG. 3A shows a semiconductor device after formation of a lower electrode of polycrystalline silicon, and FIG. 3B shows the semiconductor device after formation of an HSG on a surface of the lower electrode of polycrystalline silicon. FIG. 4 shows results of evaluating the reliability of a capacitor.

The single-wafer processing apparatus shown in FIG. 1 can consecutively process a wafer in a single device without exposure to an atmosphere. The single-wafer processing apparatus has five chambers including a preliminary chamber 1 and process chambers 2, 3, 4, and 5. Different processes can be performed in the respective chambers.

A wafer to be processed is transferred from a transfer device to the preliminary chamber 1, where a pressure and a temperature are preliminarily set at predetermined values. The wafer in the preliminary chamber 1 is in a state shown in FIG. 3A or FIG. 3B. FIG. 3A shows a state in which polycrystalline silicon is formed as a lower electrode of capacitors. FIG. 3B shows a state in which an HSG is further formed on a surface of the polycrystalline silicon so as to have irregularities on a surface thereof.

In the process chamber 2, the polycrystalline silicon is subjected to a heat treatment under a PH₃ atmosphere so as to dope an impurity of phosphorus into the polycrystalline silicon.

Subsequently, silicon nitride is deposited in the process chamber 3. An oxidation process (Rapid Thermal Oxidation: RTO) is performed in the process chamber 4 to reform the silicon nitride.

Further, an Al₂O₃ film or an aluminate film is deposited in the process chamber 5 by an ALD method.

The single-wafer processing apparatus shown in FIG. 1 can consecutively process a wafer without exposure to an atmosphere. When another apparatus is used, it is also necessary to prevent a surface of a wafer from being oxidized by exposure of the wafer to an atmosphere after an impregnation of an impurity. Particularly, it is necessary to deposit silicon nitride subsequently after a heat treatment under PH₃.

In a case where the surface of the polycrystalline silicon has small irregularities as shown in FIG. 3A, a plasma treatment is also effective as the heat treatment under PH₃. In the present invention, a heat treatment under an oxidizing atmosphere is necessary before formation of an Al₂O₃ film or an aluminate film, such as HfAlO, TaAlO, or ZrAlO, having a low oxygen diffusibility. Further, a heat treatment may be performed under an oxidizing atmosphere for another purpose after the formation of the alumina film or the aluminate film. For example, a heat treatment may be performed in order to reduce organic impurities contained in a material of the Al₂O₃ film or the like. Since the Al₂O₃ film has a low oxygen diffusibility, the silicon nitride film is oxidized and hence changed into a silicon oxide film to a very limited extent by the heat treatment under an oxidizing atmosphere. Accordingly, a problem that an oxidation process after deposition of a tantalum pentoxide (Ta₂O₅) film increases a film thickness of a silicon oxynitride film does not arise unlike the prior art.

Thus, even if a heat treatment is performed after the deposition of the Al₂O₃ film, oxidation is not caused to an interface between the Al₂O₃ film and the silicon electrode. Assuming that the oxidation temperature is increased to provide strong oxidation, Al₂O₃ is crystallized but the permittivity does not change. A leakage current is increased.

In order to prevent a leakage current, according to the present invention, the silicon nitride film is directly oxidized and reformed before the formation of the Al₂O₃ film or the aluminate film. An insulator film based on a silicon oxide film is formed between the lower electrode of polycrystalline silicon and the dielectric film. According to results of experiments conducted by the inventor, it was confirmed that the quality of an Al₂O₃ film or an aluminate film formed by an ALD method was improved by directly oxidizing and reforming a silicon nitride film before the formation of the Al₂O₃ film or the aluminate film.

When a dielectric film is crystallized by the heat treatment after formation of the dielectric film as with the prior art, heat treatment conditions are determined mainly by the quality and thickness of the dielectric film. These heat treatment conditions are excessive to a silicon nitride film. Accordingly, the silicon nitride film is reformed more than necessary. As a result, the capacitance is problematically reduced.

However, according to the present invention, since a silicon nitride film is directly oxidized before formation of a dielectric film, oxidation conditions can be determined only by the silicon nitride film and are thus easy to control. Therefore, the silicon nitride film can be reformed to a minimum extent. Since the silicon nitride film is not excessively reformed, it is possible to prevent reduction of the capacitance.

It is desirable that the silicon nitride film is processed under optimal oxidation conditions under an oxygen atmosphere or an NO atmosphere at a temperature of 700° C. to 800° C. for 30 seconds to 120 seconds. Oxidation under such conditions can prevent excessive reformation of the silicon nitride film and provide a capacitor having a large capacitance. The silicon nitride film can be formed by a CVD method. However, it is desirable that the silicon nitride film is formed by an ALD method because the ALD method can provide smaller and uniform film thickness of the silicon nitride film.

Although the single-wafer processing apparatus has been described above, a batch type wafer processing apparatus may be used to process a wafer.

Referring to FIG. 2, the batch type wafer processing apparatus has a container 11, heaters 12 mounted in the container 11, and a process chamber (vessel) 13 made of quartz. Wafers 14 are housed in a wafer carrier 15 and processed by gases supplied from a reactive gas supply portion 16. The interior of the process chamber 13 maintained under a predetermined pressure by a vacuum pump (not shown). When a process recipe is changed, types of gases supplied from the reactive gas supply portion 16 are changed. Thus, the reactive gas supply portion 16 is configured to selectively supply a plurality of types of gases.

In the batch type wafer processing apparatus, the wafers 14 housed in the wafer carrier 15 are set in the process chamber 13. These wafers 14 are subjected to a heat treatment under PH₃, and then a silicon nitride film is deposited on the wafers 14 by an ALD method. The oxidation heat treatment and the formation of the Al₂O₃ film or the aluminate film may be performed in the same batch furnace. Processes before and after the formation of the silicon nitride may be performed in another batch furnace. If a heat treatment is to be performed in order to remove organic impurities in the Al₂O₃ film or the aluminate film after the formation of the Al₂O₃ film or the aluminate film, then the heat treatment may be performed under such conditions that the heat treatment also serves as a slow cooling heat treatment for the purpose of gettering.

Next, a manufacturing process of a semiconductor device having capacitors will be described with reference to FIGS. 3A and 3B.

The capacitors shown in FIGS. 3A and 3B are provided in a DRAM memory cell portion and are cup-type capacitors, which are most generally used in DRAMs. FIGS. 3A and 3B show 2-bit memory cells connected to a common bit line.

Referring to FIG. 3A, shallow trench isolation (STI) insulator films 22 are formed in a silicon substrate 21.

A gate insulator film is deposited, and gate electrodes 23 are formed.

A first interlayer dielectric film is deposited, and first contacts 24 are formed in the first interlayer dielectric film.

A second interlayer dielectric film is deposited on the first interlayer dielectric film, and an opening is formed in the second interlayer dielectric film to wire a bit line 25.

Further, a third interlayer dielectric film is deposited on the second interlayer dielectric film, and openings are formed in the second and third interlayer dielectric films so as to form first through-holes 26.

A silicon oxide film is deposited as a fourth interlayer dielectric film on the overall surface of the wafer so as to have a thickness of several micrometers.

Subsequently, openings are formed in the silicon oxide film by photolithography and dry etching.

Next, polycrystalline silicon 27 containing phosphorus is formed on the overall surface of the wafer and etched back so as to form silicon electrodes.

Referring to FIG. 3B, hemispherical silicon grains (HSG) 28 having irregularities are formed on a surface of the polycrystalline silicon 27 in order to increase a capacity of the capacitors. There are papers and references regarding HSG technology for providing irregularities on a surface of polycrystalline silicon. Accordingly, such HSG technology will not be described here. For example, details of HSG technology are described in the paper of Watanabe et al., Technical Digests of 1992 International Electron Device Meeting, IEEE, page 259 and in the aforementioned first reference.

A heat treatment is performed under an atmosphere including PH₃ in a state shown in FIG. 3B in order to increase the phosphorus concentration in the polycrystalline silicon 27.

Then, a silicon nitride film is formed by an ALD method.

Subsequently, a heat treatment is performed under an oxidizing atmosphere to reform a surface of the silicon nitride film. The heat treatment under an oxidizing atmosphere is for improving the quality of a film at an interface between an Al₂O₃ film to be formed and the polycrystalline silicon containing a high phosphorus concentration. Examples of the oxidizing atmosphere include an oxygen atmosphere, an ozone atmosphere, an NO atmosphere, and an N₂O atmosphere.

After the oxidation, a dielectric having a low oxygen diffusibility is formed by an ALD method. Examples of the dielectric having a low oxygen diffusibility include an Al₂O₃ film and aluminate films containing Al, such as HfAlO, TaAlO, and ZrAlO. The dielectric film may have a single-layered structure. Alternatively, the dielectric film may be formed by a plurality of layers.

Then, a metal for an upper electrode is formed and covered with a protective insulator film. Thus, a semiconductor device having capacitors is produced.

The reliability of capacitors produced by a manufacturing method according to the present invention was tested.

FIG. 4 shows elapsed time (time to breakdown tBD) and defects produced when voltages of 6.1 V, 5.8 V, and 5.2 V were applied to the capacitor. Solid lines represent an example of the present invention in which an oxidation heat treatment was performed before deposition of Al₂O₃. Dashed lines represent a comparative example in which an oxidation heat treatment was performed after deposition of Al₂O₃.

In the example of the present invention, silicon nitride was formed by rapid thermal nitridation (RTN) under 700° C. for 60 seconds. An Al₂O₃ film was deposited at 400° C. so as to have a thickness of 4 nm by an ALD method. The oxidation heat treatment before the deposition of the Al₂O₃ film was performed by rapid thermal oxidation (RTO) under an oxygen atmosphere at 700° C. for 120 seconds. In the comparative example, an Al₂O₃ film was deposited at 400° C. so as to have a thickness of 4 nm by an ALD method. The oxidation heat treatment after the deposition of the Al₂O₃ film was performed by rapid thermal oxidation (RTO) under an oxygen atmosphere at 700° C. for 120 seconds.

As is apparent from FIG. 4, the example of the present invention in which the oxidation heat treatment was performed before the deposition of the Al₂O₃ film could prevent generation of accidental defects more effectively than the comparative example.

Further, the temperature of RTN was changed into 600° C., 700° C., and 800° C., respectively, and the oxidation heat treatment before the deposition of the Al₂O₃ film was performed at 700° C. by RTO. Resultant capacitors which are not shown in FIG. 4, had substantially the same capacitance as the above example. As the temperature of RTN is higher, the silicon nitride has a larger thickness. If the silicon nitride is thick, then oxidation does not proceed in the oxidation heat treatment. These effects were considered to be compensated each other, so that the capacitors had substantially the same capacitance.

The capacitors with the same capacitance had substantially the same leakage current irrespective of the temperature of RTN. The leakage current of the capacitors subjected to the oxidation heat treatment was about a half of the leakage current of the capacitors subjected to no oxidation heat treatment.

Additionally, after a silicon nitride film was formed with a thickness of 1 nm, a heat treatment was performed under an NO atmosphere at 700° C., 800° C., and 900° C. for 60 seconds. The capacitance of the capacitors was hardly reduced in the experiments of 700° C. and 800° C. The leakage current was not more than 1×10⁻⁸ cm⁻² at 1 V.

According to the present invention, impregnation of an impurity into a lower electrode of polycrystalline silicon and formation of a silicon nitride film are successively conducted to produce capacitors in a semiconductor device. Further, the silicon nitride film is oxidized. A dielectric film having a low oxygen diffusibility, such as an alumina film, is formed by an ALD method.

Since the silicon nitride film is directly oxidized before the formation of the alumina film, the reformation of the silicon nitride film can be limited to a minimum range so as to prevent a leakage current and reduction of the capacitance.

Further, the present invention has an advantage that the quality of the dielectric film formed by an ALD method can be improved by reformation of the silicon nitride film.

Furthermore, when the silicon nitride film is deposited by an ALD method, the thickness of the silicon nitride film can be made smaller and uniform.

The oxidation heat treatment conditions can be determined based on the film thickness or the quality of the silicon nitride film. When the silicon nitride film has a small thickness, it is likely to be oxidized. Accordingly, the oxidation heat treatment conditions for a silicon nitride film having a small thickness tend to have a lower temperature and a shorter process time as compared to those for a silicon nitride film having a large thickness.

Further, when the silicon nitride deposited by an ALD method or a CVD method contains many impurities such as carbon and hydrogen, these impurities are removed by the oxidation. Accordingly, a higher temperature and a longer process time can be achieved as compared to a thermal nitride film having the same film thickness. A silicon nitride film was formed with a thickness of 1 nm by an ALD method. A heat treatment was performed under an oxygen atmosphere at 800° C. for 30 seconds. Then, an Al₂O₃ film was formed with a thickness of 4 nm. This example also showed characteristics equivalent to those shown in FIG. 4.

Although certain preferred embodiments of the present invention have been shown and described in detail, it should be understood that various changes and modifications may be made therein without departing from the scope of the appended claims.

What is claimed is:

1. A method of manufacturing a semiconductor device in which a capacitor is formed, the capacitor having a lower electrode made of polycrystalline silicon and a dielectric film including aluminum, the method comprising the steps of:
doping an impurity into the lower electrode;
forming a silicon nitride film on the lower electrode without exposure to an atmosphere subsequently to the doping step of the impurity;
oxidizing the silicon nitride film; and
forming the dielectric film on the oxidized silicon nitride film.

2. The method according to claim 1, wherein the silicon nitride film is formed by an atomic layer deposition method.

3. The method according to claim 1, wherein the oxidizing step of the silicon nitride film is conducted under an atmosphere including one of oxygen, ozone, NO, and N₂O.

4. The method according to claim 1, wherein the oxidizing step of the silicon nitride film is conducted under an oxygen atmosphere or an NO atmosphere at a temperature of 700° C. to 800° C. for 30 seconds to 120 seconds.

5. The method according to claim 1, wherein the dielectric film is made of a dielectric material having a low oxygen diffusibility.

6. The method according to claim 5, wherein the dielectric film is made of a dielectric material selected from a group consisting of an alumina film and an aluminate film including one of HfAlO, TaAlO, and ZrAlO.

7. The method according to claim 1, wherein the impurity is doped into the lower electrode by a heat treatment under an atmosphere including phosphine.

8. The method according to claim 1, wherein the dielectric film is formed by an atomic layer deposition method.

9. The method according to claim 1, further comprising roughening a surface of the lower electrode.

10. The method according to claim 1, wherein the lower electrode is formed like a cup.

11. A semiconductor device comprising the capacitor manufactured by the method according to claim 1.

12. The semiconductor device according to claim 11, wherein the semiconductor device is a dynamic random access memory including the capacitor as a capacitor of a memory cell.
